(19) United States
(12) Patent Application Publication
(10) Pub. No.: US 2025/0298067 A1
(43) Pub. Date: Sep. 25, 2025

(54) FAULT LINE SELECTION METHOD, SYSTEM, AND READABLE STORAGE MEDIUM FOR A DISTRIBUTION NETWORK

(71) Applicant: Kunming University of Science and Technology, Kunming (CN)

(72) Inventors: Hongchun SHU, Kunming (CN); Jun DONG, Kunming (CN); Fei XIAO, Kunming (CN); Yutao TANG, Kunming (CN); Zhiheng YANG, Kunming (CN); Yiming HAN, Kunming (CN)

(73) Assignee: Kunming University of Science and Technology, Kunming (CN)

(21) Appl. No.: 19/026,621

(22) Filed: Jan. 17, 2025

(30) Foreign Application Priority Data
Feb. 4, 2024 (CN) 202410157968.9
Mar. 21, 2024 (CN) 202410324639.9

(51) Int. Cl. G01R 31/08

(52) U.S. Cl. CPC G01R 31/086

(57) ABSTRACT

A method, system, and readable storage medium for fault line selection in distribution networks is provided. The method includes: obtaining the zero-sequence current of each feeder and the zero-sequence voltage of the busbar within a preset time window after a fault occurs; using these to process the feeder's short-time window zero-sequence instantaneous power curve cluster in the distribution network through KPCA (Kernel Principal Component Analysis) for dimensionality reduction, determining the principal component scores; and performing BIRCH (Balanced Iterative Reducing and Clustering using Hierarchies) clustering based on these scores to identify whether a feeder is faulted. This clustering process allows for precise and rapid identification of the faulted feeder, even when the current is small, improving detection accuracy. This solves the problem of quickly identifying the faulted feeder in a small current grounding distribution network during single-phase grounding faults.

### CROSS REFERENCE TO THE RELATED APPLICATIONS

This application is based upon and claims priority to Chinese Patent Applications No. 202410157968.9, filed on Feb. 4, 2024 and No. 202410324639.9, filed on Mar. 21, 2024, the entire contents of which are incorporated herein by reference.

### TECHNICAL FIELD

The present invention relates to the technical field of power systems, and more specifically to a fault line selection method, system, and readable storage medium for a distribution network.

### BACKGROUND

With the rapid development of distribution networks in our country, the number and scale of these networks are gradually increasing, which has significantly added to the workload of operating and maintaining the distribution networks. Effectively ensuring and enhancing the safe and reliable operation of distribution networks is crucial for the safety and reliability of power supply for users. Consequently, power supply enterprises face a significant challenge: how to continuously guarantee and improve the safety and reliability of distribution networks.

In China, the neutral point of 10 kV distribution networks is generally either ungrounded or grounded through a resonance method. When a single-phase grounding fault occurs, the current flowing through the fault point is very small, and it does not affect the system's symmetry, allowing for fault-tolerant operation for a period of time, thus, it is referred to as a low-current grounding system. The main advantage of a low-current grounding system is that the current flowing into the ground is minimal, which means that some transient faults, which may cause disturbances, do not trigger protective actions, thereby effectively enhancing the reliability of power supply. Among various short-circuit faults, approximately 70% of power outages are caused by single-phase grounding faults in distribution network lines. Furthermore, a significant portion of these single-phase grounding faults is due to grounding arc faults. If not addressed for a long time, these can easily lead to fire accidents. Especially in recent years, with rapid economic development and the increasing scale of urban areas, the proportion of cable lines invested in distribution network lines has risen sharply. When affected by various factors, single-phase grounding faults can lead to a significant increase in the system's capacitance to ground, resulting in larger grounding currents, making it difficult for arcs to extinguish naturally. Prolonged operation under these conditions can easily damage equipment and lines, potentially leading to progressive faults or even wildfires. Current research indicates that single-phase grounding faults in distribution networks can directly lead to are faults, which are difficult to extinguish during transient processes. Therefore, it is crucial to promptly isolate the fault during a single-phase grounding fault to prevent its development into an arc fault.

In the relevant technical solutions for distribution networks, the neutral point of the distribution network is typically either ungrounded or grounded through a resonance method. When a single-phase grounding fault occurs, the current flowing through the fault point is very small, and it does not affect the system's symmetry, allowing for fault-tolerant operation for a certain period; thus, it is referred to as a low-current grounded distribution network. The main advantage of a low-current grounded distribution network is that the current flowing into the ground is minimal, which means that some transient interference faults do not trigger protective actions, effectively enhancing the reliability of power supply.

However, during the conception and implementation of this solution, the inventor identified at least the following drawbacks: Due to the relatively low current in the low-current grounded distribution network, traditional fault line selection devices often struggle with identifying faulted feeders when a single-phase grounding fault occurs, leading to insufficient detection accuracy.

The KPCA-BIRCH clustering algorithm performs nonlinear transformations using kernel functions based on Principal Component Analysis (PCA), further mapping the dataset into a higher-dimensional feature space where the data can be linearly separated. This allows the original data's main information to be expressed using lower-dimensional data. Subsequently, the BIRCH algorithm is applied for unsupervised clustering of the resulting data to determine the optimal clustering data and the number of clusters. Compared to the PCA algorithm, the KPCA-BIRCH algorithm is better suited for handling nonlinear equations in scenarios like distribution network faults. Through data dimensionality reduction and the fusion of dual algorithms for unsupervised clustering, it effectively achieves high precision and efficiency in clustering under adaptive conditions without rigid clustering features. This significantly improves the accuracy of fault line selection and reduces the robustness issues associated with previous line selection algorithms.

### SUMMARY

The main objective of the present invention is to provide a fault line selection method for a distribution network, aimed at addressing the issue of how to quickly identify faulted feeders when a single-phase grounding fault occurs in a low-current grounded distribution network.

To achieve the above objective, the present invention provides a fault line selection method for a distribution network, which includes:
Obtaining the zero-sequence current of each feeder and the zero-sequence voltage of the bus within a preset time window after a fault occurs in the distribution network;
Based on the zero-sequence current and zero-sequence voltage, the feeders in the distribution network are processed through the KPCA algorithm to perform a two-dimensional transformation of the zero-sequence instantaneous power curve cluster within a preset short time window, in order to determine the corresponding principal component scores.

Performing BIRCH clustering based on the principal component scores to determine whether the feeder is a faulted feeder.

Optionally, before the step of processing the feeders in the distribution network through the KPCA algorithm to perform a two-dimensional transformation of the zero-sequence instantaneous power curve cluster within a preset short time window and determining the corresponding principal component scores based on the zero-sequence current and zero-sequence voltage, the method further includes:
Obtaining first extracted data and using this data as the upper limit of the short-time window, wherein the first extracted data is taken from the interval before the fault by a first preset time duration;
Obtaining second extracted data and using this data as the lower limit of the short-time window, wherein the second extracted data is taken from the interval after the fault by a second preset time duration;
Determining the short-time window extraction interval based on the upper and lower limits of the short-time window;
Determining the zero-sequence instantaneous power curve cluster within the short-time window extraction interval as the short-time window zero-sequence instantaneous power curve cluster; Wherein, the first preset time duration is shorter than the second preset time duration.

Optionally, the short time window's zero-sequence instantaneous power curve cluster is a two-dimensional curve cluster. The step of determining the principal component scores of the zero-sequence current and zero-sequence voltage within the short time window's zero-sequence instantaneous power curve cluster includes:

Determining the target instantaneous power curve within the short time window's zero-sequence instantaneous power curve cluster based on the zero-sequence current and zero-sequence voltage;
Determining the two-dimensional coordinates of the target instantaneous power curve based on the KPCA algorithm, where the two-dimensional coordinates represent the fault zero-sequence power of the feeder;
Using the two-dimensional coordinates as the principal component scores.

The two-dimensional coordinates are obtained through the KPCA algorithm, and the formula is as follows:

$$Γ ( ϕ ) = \frac{1}{N} {\sum }_{i = 1}^{N} ϕ ( {x}_{1} ) {ϕ ( {x}_{i} )}^{T} ;$$

$$K α = λ α$$

Where Γ(ϕ) is the generating matrix of the feature space, ϕ(xᵢ), . . . , ϕ(xₙ) represents the feature samples in the feature space, N is the number of samples, K is the kernel matrix, the elements of the matrix are Kᵢⱼ=k(xᵢ,xⱼ)=ϕ(xᵢ)^{T}ϕ(xⱼ), α is the eigenvalue, and k(xᵢ,xⱼ) is the kernel function.

Optionally, the step of determining the faulted feeder in the distribution network using BIRCH clustering based on the principal component scores includes:
Grouping the two-dimensional curve cluster to discover the existing fault patterns within the data through an unsupervised clustering approach, thereby mining the internal coupling relationships of the data;
The unsupervised clustering method is to automatically and unsupervisedly discover the existing fault modes in the data without setting the number of clustering hierarchies by anyone.

Determining the optimal clustering data value k through the BIRCH algorithm, and iterating the optimal hierarchical number by jointly utilizing the silhouette coefficient Si and the Calinski-Harabasz (CH) index; The larger the values of silhouette coefficient Si and CH index are, the better the number of clusters is.

Simultaneously determining whether the feeders associated with the principal component scores are normal feeders or faulted feeders; The optimal clustering data value k is set to two hierarchical levels: 1 and 2.

When the optimal clustering data value k is 1, it indicates that the fault does not belong to the feeder, thereby determining that the feeders associated with the principal component scores are normal feeders;

When the optimal clustering data value k is 2, it indicates that the fault belongs to the feeder, The BIRCH algorithm will give sensitive prompts for outliers (fault points), thereby determining that the feeders associated with the principal component scores are faulted feeders;

The BIRCH clustering algorithm is defined by the following formula:

$${S}_{i} = \frac{b ( i ) - a ( i )}{max \{ a ( i ) , b ( i ) \}} ;$$

$$CH = \frac{B ( n - k )}{W ( k - 1 )}$$

Where k is the optimal clustering data value, a(i) represents the average distance from point i to all other points within its cluster; b(i) denotes the minimum average distance from point i to all points in any cluster that does not contain it; B is the variance between different clusters; W is the variance of the data points within all clusters; n is the total number of data points; and the CH value relates to the number of clusters and the trace of the between-cluster deviation matrix.

Optionally, after the step of obtaining the zero-sequence current of each feeder and the zero-sequence voltage of the bus within a preset time window after a fault occurs in the distribution network, it further includes:

Determining whether the zero-sequence voltage is greater than a preset phase voltage threshold. If so, executing the step of determining the corresponding principal component scores of the feeders in the preset short-time window zero-sequence instantaneous power curve cluster based on the zero-sequence current and zero-sequence voltage.

In addition, to achieve the aforementioned objectives, the present invention also provides a fault line selection system for a distribution network, which comprises:
A data acquisition module, used for obtaining the zero-sequence current of each feeder and the zero-sequence voltage of the bus within a preset time window after a fault occurs in the distribution network;
A numerical calculation module, used for determining the corresponding principal component scores of the feeders in the preset short-time window zero-sequence instantaneous power curve cluster based on the zero-sequence current and zero-sequence voltage.

A logic determination module, used for determining whether the feeder is a faulted feeder based on the principal component scores.

Optionally, the data acquisition module further includes:

A zero-sequence voltage acquisition unit, used for collecting the zero-sequence voltage of the busbar through a voltage transformer installed on the busbar.

A zero-sequence current acquisition unit, used for collecting the zero-sequence current of each feeder through current transformers installed on the respective feeders.

Optionally, the numerical computation module further includes:
A signal calculation unit, used for generating a trigger signal when the instantaneous value of the collected zero-sequence voltage exceeds a preset voltage threshold;
An instantaneous power curve calculation unit, used for determining the target instantaneous power curve within the short-time window zero-sequence instantaneous power curve cluster based on the zero-sequence current and zero-sequence voltage;
A KPCA calculation unit, used for determining the two-dimensional coordinates of the target instantaneous power curve based on the KPCA-BIRCH clustering analysis method, where the two-dimensional coordinates represent the fault zero-sequence power of the feeder.

Optionally, the logic judgment module further includes:
A zero-sequence voltage judgment unit, used for determining whether the zero-sequence voltage is greater than a preset phase voltage threshold;
Where, if so, executing the step of determining the corresponding principal component scores of the feeders in the preset short-time window zero-sequence instantaneous power curve cluster based on the zero-sequence current and zero-sequence voltage;
A fault line selection judgment unit, used for determining whether the feeder is a faulted feeder after performing BIRCH clustering on the principal component scores.

In addition, to achieve the aforementioned objectives, the present invention also provides a computer-readable storage medium, on which is stored a fault line selection program for a distribution network. When executed by a processor, the fault line selection program implements the steps of the fault line selection method for a distribution network as described above.

The embodiments of the present invention provide a fault line selection method and system for a distribution network, as well as a readable storage medium. By extracting the zero-sequence current of the feeder and the zero-sequence voltage of the bus at intervals of a predetermined power frequency cycle after a fault occurs, the method calculates the corresponding principal component scores of the zero-sequence current and voltage within the short time window of the zero-sequence instantaneous power curve cluster. Based on the principal component scores, the method determines whether the feeder line is a faulted line. This approach enables the accurate and rapid identification of target fault feeders in the distribution network, even when the current is low, thereby enhancing detection accuracy.

### BRIEF DESCRIPTION OF THE DRAWINGS

FIG. 1 is a schematic diagram of the architecture of the fault line selection system for the distribution network related to the embodiments of the present invention.

FIG. 2 is a schematic diagram of the distribution network simulation model.

FIG. 3 is a flowchart of the first embodiment of the fault line selection method for the distribution network according to the present invention.

FIG. 4 is a schematic diagram of a single-phase grounding fault in a distribution network.

FIG. 5 is a flowchart of the second embodiment of the fault line selection method for the distribution network according to the present invention.

FIG. 6 is a flowchart of the third embodiment of the fault line selection method for the distribution network according to the present invention.

FIG. 7 is a schematic diagram of the short time window zero-sequence instantaneous power curve clusters for each feeder in the distribution network.

FIG. 8 is a flowchart of the fourth embodiment of the fault line selection method for the distribution network according to the present invention.

FIG. 9 is a schematic diagram illustrating the distribution of principal component scores between healthy lines and faulted lines obtained from KPCA-BIRCH clustering analysis results.

FIG. 10 is a flowchart of the fifth embodiment of the fault line selection method for the distribution network according to the present invention.

The realization, functional characteristics, and advantages of the present invention will be further explained in conjunction with the embodiments, with reference to the accompanying drawings.

### DETAILED DESCRIPTION OF THE EMBODIMENTS

The fault line selection method for a distribution network as described in the present invention can be applied to protect distribution networks at various voltage levels. Depending on the scenario, this method can be flexibly configured for 10-35 kV overhead lines, cable lines, and mixed overhead-cable lines. It accurately identifies single-phase grounding faults in the distribution network, enabling timely protective actions, isolation, and clearance of faults, thereby enhancing the stability of the power system.

In order to better understand the above technical solutions, the exemplary embodiments of the present disclosure will be described in more detail with reference to the accompanying drawings. Although the exemplary embodiments of the present disclosure are shown in the drawings, it should be understood that the present disclosure can be implemented in various forms and should not be limited by the embodiments set forth herein. On the contrary, these embodiments are provided so that this disclosure can be more thoroughly understood and the scope of the present disclosure can be fully conveyed to those skilled in the art.

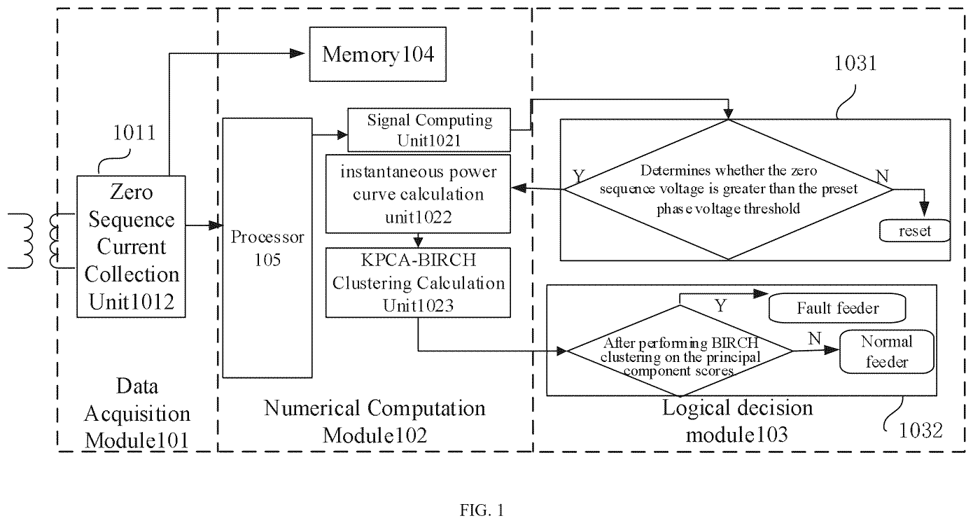

As an implementation scheme, FIG. 1 is a schematic diagram of the architecture of the hardware operating environment of the fault line selection system for a distribution network involved in the scheme of the embodiment of the present invention.

As shown in FIG. 1, the system includes a data acquisition module 101, a numerical computation module 102, and a logic judgment module 103. The data acquisition module 101 is responsible for obtaining the zero-sequence current of each feeder and the zero-sequence voltage of the bus within a preset time window after a fault occurs in the distribution network, The numerical computation module 102 is used to determine the principal component scores corresponding to the feeders in the distribution network within the preset short time window of the zero-sequence instantaneous power curve cluster, based on the zero-sequence current and zero-sequence voltage. The logic judgment module 103 is utilized to determine whether the feeder is a fault feeder based on the clustering of the principal component scores. Of which:

The data acquisition module 101 may include a zero-sequence voltage acquisition unit 1011 and a zero-sequence current acquisition unit 1012. The zero-sequence voltage acquisition unit 1011 is responsible for collecting the zero-sequence voltage of the bus through voltage transformers installed on the bus. The zero-sequence current acquisition unit 1012 is used to collect the zero-sequence current of each feeder through current transformers installed on each feeder.

The numerical computation module 102 may include a signal computation unit 1021, an instantaneous power curve computation unit 1022, and a KPCA computation unit 1023. The signal computation unit 1021 is responsible for constructing a trigger signal when the instantaneous value of the collected zero-sequence voltage exceeds a predetermined voltage threshold. The instantaneous power curve computation unit 1022 is used to determine the target instantaneous power curve within the short time window of the zero-sequence instantaneous power curve cluster based on the zero-sequence current and zero-sequence voltage. The KPCA computation unit 1023 employs the KPCA-BIRCH clustering analysis method to determine the two-dimensional coordinates of the target instantaneous power curve, where these coordinates represent the fault zero-sequence power of the feeder. These two-dimensional coordinates are then used as the principal component scores.

The logic judgment module 103 may include a zero-sequence voltage judgment unit 1031, a fault picking judgment unit 1032. the zero-sequence voltage judgment unit 1031 is used to determine whether said zero-sequence voltage is greater than a preset phase voltage threshold, wherein, if so, performing said step of determining, based on said zero-sequence current and said zero-sequence voltage, the corresponding zero-sequence instantaneous power curve clusters of a preset short window zero-sequence power curve of said feeder in the power distribution grid step of determining a principal element score; faulty line selection judgment unit 1032 for determining whether said feeder is a faulty feeder after determining the principal element score for BIRCH clustering.

In addition, the fault routing system for the power distribution grid illustrated in FIG. 1 further includes a memory 104 and a processor 105, and the memory 104 may be a high-speed RAM memory or a stable memory (non-volatile memory), such as a disk memory. The memory 103 is used to store a fault routing program for the power distribution grid as a computer-readable storage medium, and the processor 105 may be used to recall the fault routing program for the power distribution grid stored in the memory 104 and perform the following operations:
Obtaining the zero-sequence current and zero-sequence voltage at a preset power frequency interval after a fault occurs in the distribution network;
Based on said zero-sequence current and said zero-sequence voltage, a principal element score corresponding to a feeder in said distribution network in a predetermined cluster of short time window zero-sequence instantaneous power curves;
Determining whether the feeder is a faulted feeder based on the principal component scores.

In an embodiment, the processor 105 may be used to call a fault routing program for the distribution network stored in the memory 104 and perform the following operations:
Obtaining first extracted data and using this data as the upper limit of the short-time window, wherein the first extracted data is taken from the interval before the fault by a first preset time duration;
Obtaining second extracted data and using this data as the lower limit of the short-time window, wherein the second extracted data is taken from the interval after the fault by a second preset time duration;
Determining the short-time window extraction interval based on the upper and lower limits of the short-time window;
Determining the zero-sequence instantaneous power curve cluster within the short-time window extraction interval as the short-time window zero-sequence instantaneous power curve cluster;
Wherein, the first preset time duration is shorter than the second preset time duration.

In an embodiment, the processor 105 may be used to call a fault routing program for the distribution network stored in the memory 104 and perform the following operations:
determining a target instantaneous power profile in a cluster of short time window zero sequence instantaneous power profiles based on said zero sequence current and said zero sequence voltage;
Determining the two-dimensional coordinates of the target instantaneous power curve based on the KPCA algorithm, where the two-dimensional coordinates represent the fault zero-sequence power of the feeder;
Using the two-dimensional coordinates as the principal component scores.

In an embodiment, the processor 105 may be used to call a fault routing program for the distribution network stored in the memory 104 and perform the following operations:

Performing BIRCH clustering based on the principal component scores to determine whether the feeder is a faulted feeder.

In an embodiment, the processor 105 may be used to call a fault routing program for the distribution network stored in the memory 104 and perform the following operations:

Determining whether the zero-sequence voltage is greater than a preset phase voltage threshold.

If so, executing the step of determining the corresponding principal component scores of the feeders in the preset short-time window zero-sequence instantaneous power curve cluster based on the zero-sequence current and zero-sequence voltage.

Based on the above hardware architecture of a fault routing system for a power distribution network based on power system technology, an embodiment of a fault routing method for a power distribution network of the present invention is proposed.

Referring to FIG. 2, FIG. 2 shows the schematic diagram of the distribution network simulation model, the distribution network simulation model is to build the distribution network arc simulation model according to the actual operation of the distribution network, and the distribution network simulation model as shown in FIG. 2 is established by using PSCAD/EMTDC, there are six outlets of the 110 kV/10 kV substation, and there are four overhead lines, respectively L1=20 km, L2=24 km, L4=16 km, L6=12 km, and there are two pure cable lines, respectively L3=16 km, L5=15 km. 16 km, L6=12 km, and two pure cable lines, L3=16 km, L5=15 km. The positive sequence impedance of the overhead line is R1=0.4502/km, L1=1.172 mH/km, and C1=6.1 nF/km, and the zero sequence impedance is R0=0.702/km, L0=3.91 mH/km, and C0=3.8 The positive-sequence impedance of the cable feeder is R1=0.07502/km, L1=0.254 mH/km, C1=318 nF/km, and the zero-sequence impedance is R0=0.10262/km, L0=0.892 mH/km, and C0=212 nF/km. The neutral point of this distribution system is ungrounded, and a single-phase ground fault is set in the simulation model. The fault points are set at feeder L1 at 10 km, 11 km, 12 km, 13 km, 14 km, and 15 km from the first section bus, and the initial angles of the faults are all 90°, and the transition resistance is 0Ω.

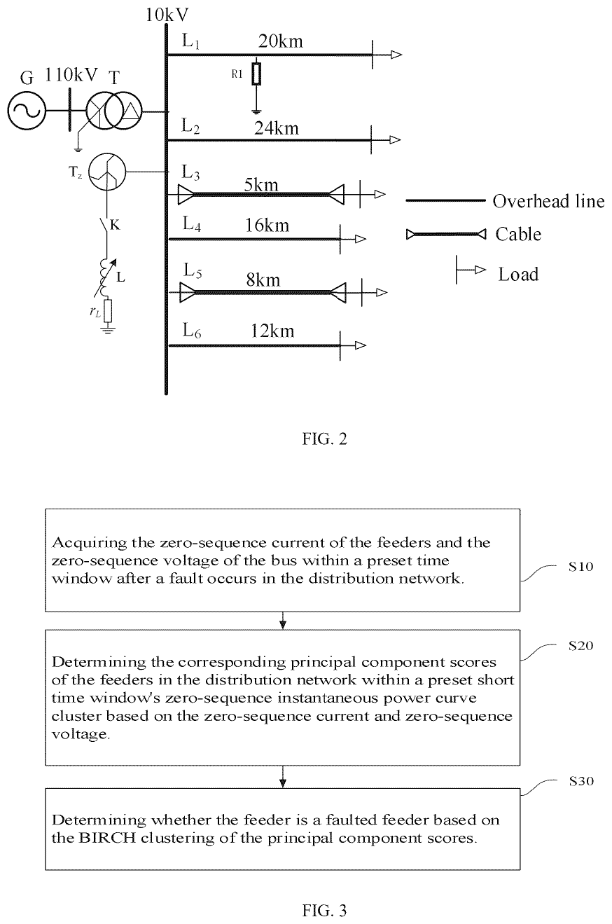

Referring to FIG. 3, in a first embodiment, said method of fault routing for a distribution network comprises the following steps:

Step S10, Obtaining the zero-sequence current of each feeder and the zero-sequence voltage of the bus within a preset time window after a fault occurs in the distribution network;

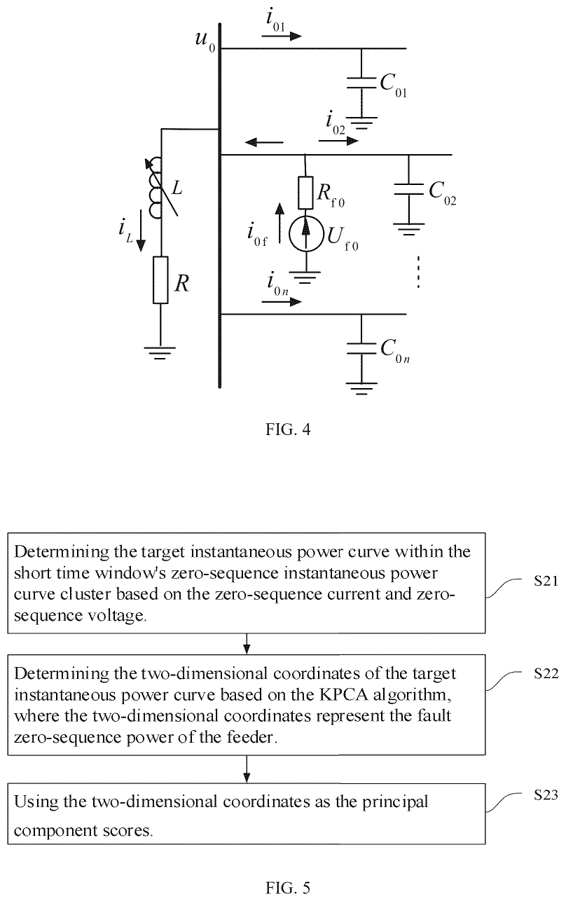

In this embodiment, with reference to FIG. 4, which shows a schematic diagram of a single-phase ground fault distribution network, when a fault occurs in the distribution network, a zero-sequence current of a feeder in the distribution network and a zero-sequence voltage of a bus at an interval of a preset period after the occurrence of the fault are first collected.

Exemplarily, the distribution network fault is a single-phase ground fault, the initial angle of the fault is 90°, and the transition resistance is 0Ω. A corresponding zero-sequence current of the feeder and a zero-sequence voltage of the bus are obtained to be generated by the distribution network line under the single-phase ground fault.

Optionally, the zero sequence voltage of the bus may be obtained by means of a voltage transformer mounted on the bus, and the zero sequence current of each feeder may be collected by means of a current transformer mounted on the respective feeder.

Optionally, the preset cycle of the power frequency can be set to one quarter of the power frequency cycle after a fault interval.

In this embodiment, the zero-sequence current refers to an average value of the three-phase currents of the feeder, while the zero-sequence voltage refers to an average value of the three-phase voltages of the bus. These data can be used as inputs for subsequent steps.

Step S20, based on said zero-sequence current and said zero-sequence voltage, determining a master element score corresponding to a feeder in said distribution network in a predetermined cluster of short time window zero-sequence instantaneous power curves;

In this embodiment, after obtaining the zero-sequence currents of the feeders and the zero-sequence voltages of the buses, a short time window zero-sequence instantaneous power curve cluster technique is used to calculate a principal element score for each feeder within a predetermined time window. Specifically, the short time window zero-sequence instantaneous power curve clustering technique may take the zero-sequence currents and zero-sequence voltages of the feeders as inputs and compute zero-sequence instantaneous power curves for the feeders during the time window. These power curves may be used to determine a score for each feeder within a predetermined time window.

In this embodiment, Principal Component Score (PCS) is a data analysis technique that is typically used for downscaling and feature extraction of multi-dimensional data. In this embodiment, the Principal Component Score is used to determine faulty feeders. The principal component score is characterized as a new set of variable values obtained after linear transformation of the original data, which are ordered according to the magnitude of the variance of the data, where the first variable is called the first principal component, the second variable is called the second principal component, and so on. Each principal element represents a particular way of combining the original data in such a way that, of all possible combinations, that principal element explains the most variation in the data.

Step S30, determining whether said feeder is a faulty feeder based on said master element score. In this embodiment, after the principal element score is determined, the feeder is clustered based on the principal element score and then goes to determine whether the feeder is a faulty feeder.

Optionally, in some implementations, a master element score for each feeder within a predetermined time window may be compared to a predefined threshold. If the score exceeds the threshold, the feeder may be determined to be a faulty feeder. Otherwise, the feeder is not a faulty feeder. Among other things, different thresholds may be set to accommodate different environments and scenarios.

Optionally, in other embodiments, BIRCH clustering is performed based on said principal element score to determine whether said feeder is a faulty feeder, determining that the feeder associated with the principal element score is a faulty feeder.

In the technical solution provided in this embodiment, when a fault occurs in the distribution network, the zero-sequence current of the feeder and the zero-sequence voltage of the bus are extracted at intervals corresponding to a preset power frequency cycle after the fault. Subsequently, the principal component scores corresponding to the zero-sequence current and voltage are calculated within the short-time window zero-sequence instantaneous power curve cluster. Based on these principal component scores, clustering is performed to determine whether the feeder line in question is faulty. This approach allows for the precise and rapid identification of target faulted feeders within the distribution network, even when the current levels are relatively low, thereby enhancing detection accuracy.

Referring to FIG. 5, in a second embodiment, based on either embodiment, said step S20 comprises:
Step S21, determining a target instantaneous power curve in a cluster of short time window zero sequence instantaneous power curves based on said zero sequence current and said zero sequence voltage;
Step S22, determining, based on a KPCA algorithm, two-dimensional coordinates of said target instantaneous power curve, said two-dimensional coordinates indicating a faulted zero-sequence power of said feeder;
Step S23, using said two-dimensional coordinates, as said master element score.

Optionally, in this embodiment, a zero-sequence current of a feeder and a zero-sequence voltage of a bus at a predetermined interval of an power frequency cycle after a fault occurs in the distribution network are obtained. Based on said zero-sequence current and said zero-sequence voltage, a target instantaneous power curve in a cluster of short time window zero-sequence instantaneous power curves is determined.

Specifically, it can be processed according to the following steps:

First, the zero-sequence current and zero-sequence voltage are respectively subjected to Discrete Fourier Transform (DFT) to obtain their frequency spectra, where only the fundamental component (i.e., the IF component) needs to be considered.

In the next step, the zero-sequence instantaneous power is calculated and divided into several segments according to the time window, and each segment contains data from several IF cycles. For each time segment, their zero-sequence instantaneous power curves are combined into an average curve to obtain a short time window zero-sequence instantaneous power curve.

In a next step, said target instantaneous power curve is processed using the KPCA algorithm to determine two-dimensional coordinates representing the faulted zero-sequence power of said feeder. Specifically, the processing may be performed according to the following steps:

(1) For each target instantaneous power curve, calculate its first n principal element scores to obtain an n-dimensional vector.

(2) Put the n-dimensional vectors of all target instantaneous power curves in a matrix and perform KPCA dimensionality reduction to obtain a two-dimensional coordinate system.

(3) The coordinates of each target instantaneous power curve in this two-dimensional coordinate system are the desired two-dimensional coordinates, and the horizontal coordinates are the first principal element scores of that target instantaneous power curve.

(4) Taking the transverse coordinate of said two-dimensional coordinate, as the principal element score of said feeder. Specifically, for each feeder, the transverse coordinate of its corresponding target instantaneous power curve is taken as the principal element score for that feeder. Exemplarily, there are two main element scores, KP1 and KP2, and a 2-dimensional vector instantaneous power matrix APO is formed based on KP1 and KP2

$$Δ {P}_{0} = [ \begin{matrix}Δ {P}_{01} ( 1 ) & Δ {P}_{01} ( 2 ) & Δ {P}_{01} ( 3 ) & … & Δ {P}_{01} ( 25 ) \\ ⋮ & ⋮ & ⋮ & & ⋮ \\ Δ {P}_{06} ( 1 ) & Δ {P}_{06} ( 2 ) & Δ {P}_{06} ( 3 ) & … & Δ {P}_{06} ( 25 ) \\ … & … & … & & …\end{matrix} ]$$

In this matrix, 5 sample points before the first instant of the fault and 20 sample points after the first instant of the fault are selected for each sample, and a 36×25 matrix is formed from 36 historical sample data and KPCA-BIRCH clustering is performed. The cumulative contribution of the fault informativeness contained in KP1 and KP2 is greater than 97%. Using KP1 and KP2 to represent the fault zero sequence power, two-dimensional coordinates X (KP1, KP2) representing the fault zero sequence power of said feeder are obtained

Finally, the two-dimensional coordinates X, i.e., (KP1, KP2), are used as the principal element score so as to carry out the determination of the faulty feeder based on the values utilizing BIRCH clustering.

It is to be noted that different feeders correspond to different zero sequence currents, and hence the corresponding target instantaneous power curves in the short time window zero sequence instantaneous power curve clusters are also different.

In the technical solution provided in this embodiment, the target instantaneous power curve is determined by combining the zero-sequence current and the zero-sequence voltage, which makes it possible to accurately and quickly determine the target faulty feeder in the distribution network even when the power flow rate of the distribution network is small, and improves the detection accuracy.

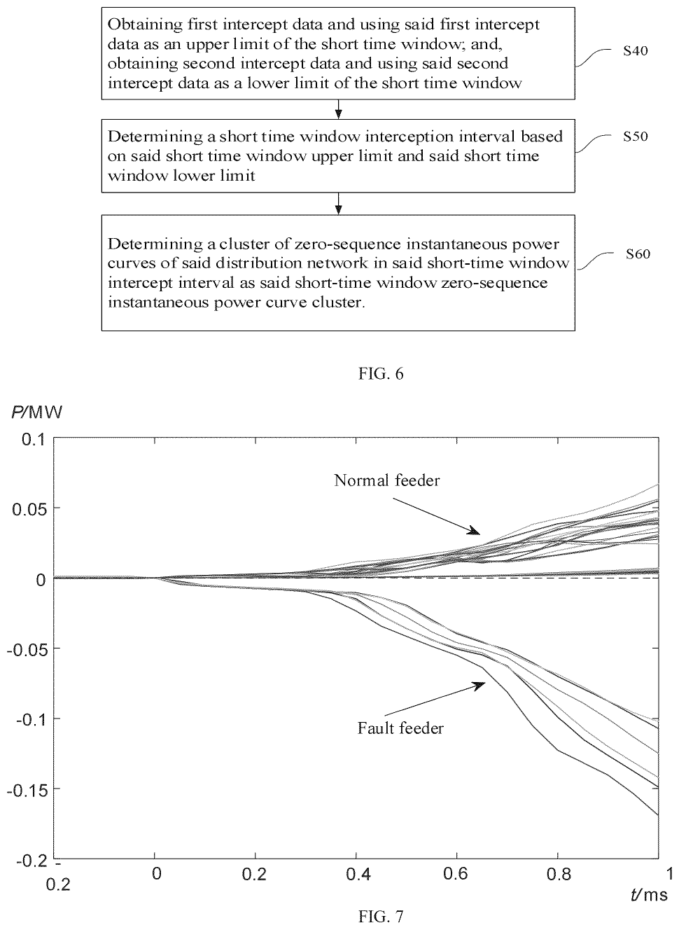

Referring to FIG. 6, in the third embodiment, based on either embodiment, said step S10 is preceded by further comprising:
Step S40, obtaining first intercept data and using said first intercept data as an upper limit of the short time window; and, obtaining second intercept data and using said second intercept data as a lower limit of the short time window;
Step S50, determining a short time window interception interval based on said short time window upper limit and said short time window lower limit;
Step S60, determining a cluster of zero-sequence instantaneous power curves of said distribution network in said short-time window intercept interval as said short-time window zero-sequence instantaneous power curve cluster.

Optionally, a method of how to construct a cluster of zero-sequence instantaneous power curves for a short-time window is provided in this embodiment. In this embodiment, the size of an interception interval of the short-time window is first determined, and a first interception data intercepted at a first predetermined length of time in a pre-fault interval is used as an upper limit of the short-time window, and a second interception data intercepted at a second predetermined length of time in a post-fault interval is used as a lower limit of the short-time window. A cluster of zero-sequence instantaneous power curves of the distribution network in the short time window interception interval is determined as said short time window zero-sequence instantaneous power curve cluster, wherein the first predetermined duration is less than the second predetermined duration

Optionally, the first preset length of time may be 0.2 ms of data at a pre-fault interval.

Optionally, the second preset duration may be data for a post-fault interval of 1 ms.

Exemplarily, referring to FIG. 7, FIG. 7 shows a schematic diagram of clusters of zero-sequence instantaneous power curves for each feeder of the distribution network in a short time window. It can be seen that there is a clear difference between a line with a fault and a sound line (normal line).

In the technical solution provided in this embodiment, the short-time window zero-sequence instantaneous power curve clusters are constituted by intercepting the zero-sequence instantaneous power curve clusters of the distribution network within the short-time window intervals, which provides a prerequisite for the subsequent determination of the main element scores corresponding to the feeders in the distribution network in the preset short-time window zero-sequence instantaneous power curve clusters based on the zero-sequence currents and zero-sequence voltages and then, by clustering the data by BIRCH clustering, thereby The target faulty feeder in the distribution network can be accurately and quickly determined even when the power flow in the distribution network is small, which improves the detection accuracy.

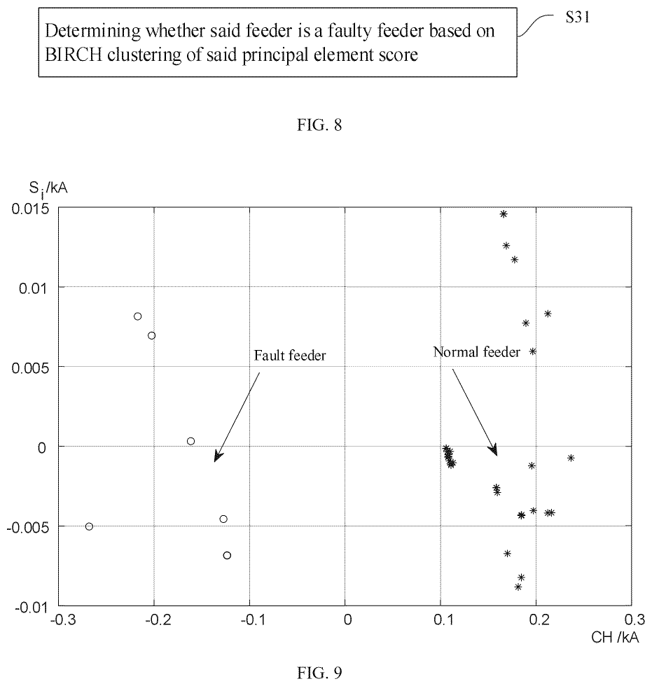

Referring to FIG. 8, in a fourth embodiment, based on either embodiment, said step S30 comprises:

S31, determining whether said feeder is a faulty feeder based on BIRCH clustering of said principal element score.

Optionally, in this embodiment, determining whether the feeder is a faulty feeder based on the BIRCH clustering of the principal element score.

Exemplarily, referring to FIG. 9, FIG. 9 shows a schematic diagram of the distribution between the principal element scores of the sound line and the faulty line obtained based on the results of the KPCA-BIRCH clustering analysis. The said two-dimensional curve clusters are grouped and automatically and unsupervised discovery of failure modes present in the data as well as mining the internal coupling relationships of the data is performed without anyone setting the number of clustering hierarchies;

Meanwhile the BIRCH algorithm uses a tree model to determine a good optimal clustering data value k. The optimal number of stratification is iterated by joint profile coefficients Si and CH metrics, which together act on the value of k. The larger the value of the two metrics, the better the number of clusters will be. It is also determined whether the feeder associated with said principal element score is a normal feeder or is a faulty feeder;

The value of k is 1 and 2 for both stratification numbers:
When said value of k is 1, it means that the fault does not belong to the feeder and it is determined that the feeder associated with said principal element score is a normal feeder;
When said value of k is 2, it indicates that the fault belongs to the feeder and the BIRCH algorithm is sensitive to the anomalies (faults), determining that the feeder associated with said principal element score is a faulty feeder;

The BIRCH clustering algorithm is defined by the following formula:

$${S}_{i} = \frac{b ( i ) - a ( i )}{max \{ a ( i ) , b ( i ) \}} ;$$

$$CH = \frac{B ( n - k )}{W ( k - 1 )}$$

Where k is the optimal clustering data value, a(i) represents the average distance from point i to all other points within its cluster; b(i) denotes the minimum average distance from point i to all points in any cluster that does not contain it; B is the variance between different clusters; W is the variance of the data points within all clusters; n is the total number of data points; and the CH value relates to the number of clusters and the trace of the between-cluster deviation matrix. Eventually, the 2D coordinate points will be effectively categorized into two feature clusters, and the principal element score that occupies fewer classes will be selected, which in turn will select the faulty feeder it corresponds to.

In the technical solution provided in this embodiment, normal feeders and faulty feeders are differentiated by the BIRCH clustering situation of the principal element scores, which makes it possible to accurately and quickly determine the target faulty feeders in the distribution network even when the power flow in the distribution network is small, and improves the detection accuracy.

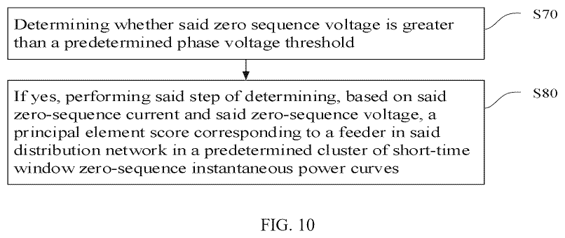

Referring to FIG. 10, in a fifth embodiment, based on either embodiment, said step S10 is followed by:
Step S70, determining whether said zero sequence voltage is greater than a predetermined phase voltage threshold;
Step S80, if yes, performing said step of determining, based on said zero-sequence current and said zero-sequence voltage, a principal element score corresponding to a feeder in said distribution network in a predetermined cluster of short-time window zero-sequence instantaneous power curves.

Optionally, in this embodiment, a busbar zero-sequence voltage sensor is provided in the distribution network, through which an instantaneous value of the busbar zero-sequence voltage is obtained. Meanwhile, a voltage threshold detection module is provided, which sends a power-up signal to the fault recording and line selection device when the instantaneous value of the busbar zero sequence voltage is greater than a preset phase voltage threshold.

The fault recording and selecting device is activated upon receipt of the power-up signal and begins to record the zero sequence voltage of each feeder for a preset period after the fault occurs. During this period, the fault recorder and selector transmits the recorded data to the host computer for subsequent data analysis.

It should be noted that, in order to ensure the accuracy and stability of the data, high-precision voltage sensors should be used, and the data should be reasonably filtered and corrected. In addition, the selection of preset period should be adjusted according to the specific situation to fully ensure the integrity and accuracy of the data.

Exemplarily, let the zero-sequence voltage of the bus be, and the voltage threshold be, where, generally taken as 0.15, indicates the rated voltage of the bus.

If is greater than, then the fault selector device is immediately activated to record the zero sequence current one week wave after the fault occurs.

In this embodiment, when the instantaneous value of the zero sequence voltage of the busbar is greater than the preset phase voltage threshold, and it is initially judged that a fault occurs in the distribution network, the fault recording line selection device is activated to perform step S20, which, in combination with the foregoing method of selecting a line for a fault in the distribution network, can make a judgment in time and accurately select a line in the event of a fault in the distribution network, which improves the accuracy of the detection and at the same time, ensures the system safety and stability.

In addition, it is understood by a person of ordinary skill in the art that all or part of the process in the method for realizing the above embodiments is possible to be accomplished by a computer program that instructs the relevant hardware to do so. The computer program comprises program instructions, and the computer program may be stored in a storage medium which is a computer-readable storage medium. The program instructions are executed by at least one processor in the fault routing system of the distribution network to implement the process steps of the embodiments of the method described above.

Accordingly, the present invention further provides a computer-readable storage medium, said computer-readable storage medium storing a fault routing program for a power distribution network, said fault routing program for a power distribution network being executed by a processor to realize the various steps of the fault routing method for a power distribution network as described in the above embodiment.

Wherein said computer-readable storage medium may be a USB flash drive, a removable hard disk, a Read-Only Memory (ROM), a diskette or a CD-ROM, and other kinds of computer-readable storage medium that can store program code.

It is to be noted that since the storage medium provided in the embodiments of the present application is the storage medium adopted for implementing the method of the embodiments of the present application, based on the method introduced in the embodiments of the present application, the person belonging to the field is able to understand the specific structure and deformation of the storage medium, and therefore no further details will be given herein. All of the storage media used in the methods of the embodiments of the present application fall within the scope of protection intended by the present application.

It should be appreciated by those skilled in the art that embodiments of the present invention may be provided as a method, system or computer program product. Thus, the present invention may take the form of a fully hardware embodiment, a fully software embodiment, or an embodiment that combines software and hardware aspects. Further, the present invention may take the form of a computer program product implemented on one or more computer-usable storage media (including, but not limited to, disk memory, CD-ROM, optical memory, and the like) that contain computer-usable program code therein.

The present invention is described with reference to flowcharts and/or block diagrams of methods, apparatus (systems), and computer program products according to embodiments of the present invention. It is to be understood that each of the processes and/or boxes in the flowchart and/or block diagram, and the combination of processes and/or boxes in the flowchart and/or block diagram, may be implemented by computer program instructions. These computer program instructions may be provided to a processor of a general-purpose computer, a special-purpose computer, an embedded processor, or other programmable data-processing device to produce a machine such that the instructions executed by the processor of the computer or other programmable data-processing device produce a device for carrying out the functions specified in the one process or multiple processes of the flowchart and/or the one box or multiple boxes of the box diagram.

These computer program instructions may also be stored in a computer-readable memory capable of directing a computer or other programmable data processing device to operate in a particular manner, such that the instructions stored in the computer-readable memory produce an article of manufacture comprising an instruction device that implements a function specified in one process or multiple processes of a flowchart and/or one box or multiple boxes of a block diagram.

These computer program instructions may also be loaded onto a computer or other programmable data processing device such that a series of operational steps are performed on the computer or other programmable device to produce computer-implemented processing, such that the instructions executed on the computer or other programmable device provide steps for implementing the functionality specified in the flowchart one process or a plurality of processes and/or the box diagram one box or a plurality of boxes.

It should be noted that any reference between brackets in a claim should not be construed as a limitation of the claim. The word “comprising” does not exclude the existence of parts or steps that are not listed in the claim. The word “one” or “a” before a component does not exclude the existence of a plurality of such components. The present invention can be realized with the aid of hardware comprising a number of different components and with the aid of a suitably programmed computer. In unit claims enumerating a number of devices, several of these devices may be specified by means of the same hardware item. The use of the words first, second, and third, etc. does not indicate any order. The words may be construed as names.

Although preferred embodiments of the present invention have been described, those skilled in the art may make additional changes and modifications to these embodiments once the basic inventive concepts are known. Therefore, the appended claims are intended to be construed to include the preferred embodiments as well as all changes and modifications that fall within the scope of the present invention.

Obviously, those skilled in the art can make various changes and variations to the present invention without departing from the spirit and scope of the present invention. Thus, to the extent that such modifications and variations of the present invention fall within the scope of the claims of the present invention and their technical equivalents, the present invention is intended to encompass such modifications and variations.

What is claimed is:

1-10. (canceled)

11. A fault line selection method for a distribution network, comprising the following steps:
obtaining a zero-sequence current of each feeder and a zero-sequence voltage of a bus within a preset time window after a fault occurs in the distribution network;
using the zero-sequence current and the zero-sequence voltage to process the feeder's short-time window zero-sequence instantaneous power curve cluster in the distribution network through Kernel Principal Component Analysis (KPCA) algorithm for dimensionality reduction to determine corresponding principal component scores; and
performing Balanced Iterative Reducing and Clustering using Hierarchies (BIRCH) clustering based on the principal component scores to identify whether the feeder is a faulted feeder.

12. The fault line selection method for the distribution network according to claim 11, wherein before the step of processing the feeder's short-time window zero-sequence instantaneous power curve cluster through the KPCA algorithm for dimensionality reduction based on the zero-sequence current and the zero-sequence voltage to determine the corresponding principal component scores, the fault line selection method further comprises:
obtaining first extracted data and using the first extracted data as an upper limit of a short-time window, wherein the first extracted data is taken from an interval before a fault by a first preset time duration;
obtaining second extracted data and using the second extracted data as a lower limit of the short-time window, wherein the second extracted data is taken from an interval after the fault by a second preset time duration;
determining a short-time window extraction interval based on the upper limit and the lower limit of the short-time window; and
determining a zero-sequence instantaneous power curve cluster within the short-time window extraction interval as the short-time window zero-sequence instantaneous power curve cluster;
wherein, the first preset time duration is shorter than the second preset time duration.

13. The fault line selection method for the distribution network according to claim 11, wherein the step of processing the feeder's short-time window zero-sequence instantaneous power curve cluster through the KPCA algorithm for dimensionality reduction based on the zero-sequence current and the zero-sequence voltage to determine the corresponding principal component scores comprises:
determining a target instantaneous power curve within the short-time window zero-sequence instantaneous power curve cluster based on the zero-sequence current and the zero-sequence voltage;
determining two-dimensional coordinates of the target instantaneous power curve based on the KPCA algorithm, wherein the two-dimensional coordinates represent a fault zero-sequence power of the feeder; and
using the two-dimensional coordinates as the principal component scores;
wherein the two-dimensional coordinates are obtained through the KPCA algorithm by the following formula:
$$Γ ( ϕ ) = \frac{1}{N} {\sum }_{i = 1}^{N} ϕ ( {x}_{i} ) {ϕ ( {x}_{i} )}^{T} ;$$
$$K α = λ α$$
wherein Γ(ϕ) is a generating matrix of a feature space, ϕ(xᵢ), . . . , ϕ(xₙ) represents feature samples in the feature space, N is a number of samples, K is a kernel matrix, elements of the kernel matrix are Kᵢⱼ=k(xᵢ,xⱼ)=ϕ(xᵢ)^{T}ϕ(xⱼ), α is an eigenvalue, and k(xᵢ,xⱼ) is a kernel function.

14. The fault line selection method for the distribution network according to claim 11, wherein the step of determining the faulted feeder in the distribution network using BIRCH clustering based on the principal component scores comprises:
grouping a two-dimensional curve cluster to discover existing fault patterns within data through an unsupervised clustering approach, thereby mining internal coupling relationships of the data;
determining an optimal clustering data value k through the BIRCH algorithm, and iterating an optimal hierarchical number by jointly utilizing a silhouette coefficient Sᵢ and a Calinski-Harabasz (CH) index; and
simultaneously determining whether feeders associated with the principal component scores are normal feeders or faulted feeders;
wherein the optimal clustering data value k is set to two hierarchical levels: 1 and 2;
when the optimal clustering data value k is 1, it indicates that a fault does not belong to the feeder, thereby determining that the feeders associated with the principal component scores are the normal feeders; and
when the optimal clustering data value k is 2, it indicates that the fault belongs to the feeder, thereby determining that the feeders associated with the principal component scores are the faulted feeders;
wherein the BIRCH clustering algorithm is defined by the following formula:
$${S}_{i} = \frac{b ( i ) - a ( i )}{max \{ a ( i ) , b ( i ) \}} ;$$
$$CH = \frac{B ( n - k )}{W ( k - 1 )}$$
wherein k is the optimal clustering data value, a(i) represents an average distance from a point i to all other points within a cluster of the point i; b(i) denotes a minimum average distance from the point i to all points in any cluster that does not contain the point i; B is a variance between different clusters; W is a variance of data points within all clusters; n is a total number of data points; and a CH value relates to a number of clusters and a trace of a between-cluster deviation matrix.

15. The fault line selection method for the distribution network according to claim 11, wherein after the step of obtaining the zero-sequence current of each feeder and the zero-sequence voltage of the bus within the preset time window after the fault occurs in the distribution network, the fault line selection method further comprises:
determining whether the zero-sequence voltage is greater than a preset phase voltage threshold; and
when the zero-sequence voltage is greater than the preset phase voltage threshold, executing the step of determining the corresponding principal component scores of feeders in the preset short-time window zero-sequence instantaneous power curve cluster based on the zero-sequence current and the zero-sequence voltage.

16. A fault line selection system for a distribution network, wherein the system comprises:
a data acquisition module, used for obtaining a zero-sequence current of each feeder and a zero-sequence voltage of a bus within a preset time window after a fault occurs in the distribution network;
a numerical calculation module, used for determining corresponding principal component scores of feeders in a preset short-time window zero-sequence instantaneous power curve cluster based on the zero-sequence current and the zero-sequence voltage; and
a logic determination module, used for determining whether the feeder is a faulted feeder based on the principal component scores.

17. The fault line selection system for the distribution network according to claim 16, wherein the data acquisition module comprises:
a zero-sequence voltage acquisition unit, used for collecting the zero-sequence voltage of the bus through a voltage transformer installed on the bus; and
a zero-sequence current acquisition unit, used for collecting the zero-sequence current of each feeder through a current transformer installed on each feeder.

18. The fault line selection system for the distribution network according to claim 16, wherein the numerical calculation module comprises:
a signal calculation unit, used for generating a trigger signal when an instantaneous value of the zero-sequence voltage exceeds a preset voltage threshold;
an instantaneous power curve calculation unit, used for determining a target instantaneous power curve within the preset short-time window zero-sequence instantaneous power curve cluster based on the zero-sequence current and the zero-sequence voltage; and
a KPCA calculation unit, used for determining two-dimensional coordinates of the target instantaneous power curve based on a KPCA-BIRCH clustering analysis method, wherein the two-dimensional coordinates represent a fault zero-sequence power of the feeder.

19. The fault line selection system for the distribution network according to claim 16, wherein the logic determination module comprises:
a zero-sequence voltage judgment unit, used for determining whether the zero-sequence voltage is greater than a preset phase voltage threshold;
wherein, when the zero-sequence voltage is greater than the preset phase voltage threshold, executing the step of determining the corresponding principal component scores of the feeders in the preset short-time window zero-sequence instantaneous power curve cluster based on the zero-sequence current and the zero-sequence voltage; and
a fault line selection judgment unit, used for determining whether the feeder is the faulted feeder after BIRCH clustering is performed on the principal component scores.

20. A computer-readable storage medium, wherein the computer-readable storage medium stores a fault line selection program for a distribution network, wherein when executed by a processor, the fault line selection program for the distribution network implements steps of the fault line selection method for the distribution network according to claim 11.

21. The fault line selection method for the distribution network according to claim 12, wherein the step of processing the feeder's short-time window zero-sequence instantaneous power curve cluster through the KPCA algorithm for dimensionality reduction based on the zero-sequence current and the zero-sequence voltage to determine the corresponding principal component scores comprises:
determining a target instantaneous power curve within the short-time window zero-sequence instantaneous power curve cluster based on the zero-sequence current and the zero-sequence voltage;
determining two-dimensional coordinates of the target instantaneous power curve based on the KPCA algorithm, wherein the two-dimensional coordinates represent a fault zero-sequence power of the feeder; and
using the two-dimensional coordinates as the principal component scores;
wherein the two-dimensional coordinates are obtained through the KPCA algorithm by the following formula:
$$Γ ( ϕ ) = \frac{1}{N} {\sum }_{i = 1}^{N} ϕ ( {x}_{i} ) {ϕ ( {x}_{i} )}^{T} ;$$
$$K α = λ α$$
wherein Γ(ϕ) is a generating matrix of a feature space, ϕ(xᵢ), . . . , ϕ(xₙ) represents feature samples in the feature space, N is a number of samples, K is a kernel matrix, elements of the kernel matrix are Kᵢⱼ=k(xᵢ,xⱼ)=ϕ(xᵢ)^{T}ϕ(xⱼ), α is an eigenvalue, and k(xᵢ,xⱼ) is a kernel function.

22. The computer-readable storage medium according to claim 20, wherein before the step of processing the feeder's short-time window zero-sequence instantaneous power curve cluster through the KPCA algorithm for dimensionality reduction based on the zero-sequence current and the zero-sequence voltage to determine the corresponding principal component scores, the fault line selection method further comprises:
obtaining first extracted data and using the first extracted data as an upper limit of a short-time window, wherein the first extracted data is taken from an interval before a fault by a first preset time duration;
obtaining second extracted data and using the second extracted data as a lower limit of the short-time window, wherein the second extracted data is taken from an interval after the fault by a second preset time duration;
determining a short-time window extraction interval based on the upper limit and the lower limit of the short-time window; and
determining a zero-sequence instantaneous power curve cluster within the short-time window extraction interval as the short-time window zero-sequence instantaneous power curve cluster;
wherein, the first preset time duration is shorter than the second preset time duration.

23. The computer-readable storage medium according to claim 20, wherein in the fault line selection method for the distribution network, the step of processing the feeder's short-time window zero-sequence instantaneous power curve cluster through the KPCA algorithm for dimensionality reduction based on the zero-sequence current and the zero-sequence voltage to determine the corresponding principal component scores comprises:
determining a target instantaneous power curve within the short-time window zero-sequence instantaneous power curve cluster based on the zero-sequence current and the zero-sequence voltage;
determining two-dimensional coordinates of the target instantaneous power curve based on the KPCA algorithm, wherein the two-dimensional coordinates represent a fault zero-sequence power of the feeder; and
using the two-dimensional coordinates as the principal component scores;
wherein the two-dimensional coordinates are obtained through the KPCA algorithm by the following formula:
$$Γ ( ϕ ) = \frac{1}{N} {\sum }_{i = 1}^{N} ϕ ( {x}_{i} ) {ϕ ( {x}_{i} )}^{T} ;$$
$$K α = λ α$$
wherein Γ(ϕ) is a generating matrix of a feature space, ϕ(xᵢ), . . . , ϕ(xₙ) represents feature samples in the feature space, N is a number of samples, K is a kernel matrix, elements of the kernel matrix are Kᵢⱼ=k(xᵢ,xⱼ)=ϕ(xᵢ)^{T}ϕ(xⱼ), α is an eigenvalue, and k(xᵢ,xⱼ) is a kernel function.

24. The computer-readable storage medium according to claim 20, wherein in the fault line selection method for the distribution network, the step of determining the faulted feeder in the distribution network using BIRCH clustering based on the principal component scores comprises:
grouping a two-dimensional curve cluster to discover existing fault patterns within data through an unsupervised clustering approach, thereby mining internal coupling relationships of the data;
determining an optimal clustering data value k through the BIRCH algorithm, and iterating an optimal hierarchical number by jointly utilizing a silhouette coefficient Sᵢ and a Calinski-Harabasz (CH) index; and
simultaneously determining whether feeders associated with the principal component scores are normal feeders or faulted feeders;
wherein the optimal clustering data value k is set to two hierarchical levels: 1 and 2;
when the optimal clustering data value k is 1, it indicates that a fault does not belong to the feeder, thereby determining that the feeders associated with the principal component scores are the normal feeders; and
when the optimal clustering data value k is 2, it indicates that the fault belongs to the feeder, thereby determining that the feeders associated with the principal component scores are the faulted feeders;
wherein the BIRCH clustering algorithm is defined by the following formula:
$${S}_{i} = \frac{b ( i ) - a ( i )}{max \{ a ( i ) , b ( i ) \}} ;$$
$$CH = \frac{B ( n - k )}{W ( k - 1 )}$$
wherein k is the optimal clustering data value, a(i) represents an average distance from a point i to all other points within a cluster of the point i; b(i) denotes a minimum average distance from the point i to all points in any cluster that does not contain the point i; B is a variance between different clusters; W is a variance of data points within all clusters; n is a total number of data points; and a CH value relates to a number of clusters and a trace of a between-cluster deviation matrix.

25. The computer-readable storage medium according to claim 20, wherein after the step of obtaining the zero-sequence current of each feeder and the zero-sequence voltage of the bus within the preset time window after the fault occurs in the distribution network, the fault line selection method further comprises:
determining whether the zero-sequence voltage is greater than a preset phase voltage threshold; and
when the zero-sequence voltage is greater than the preset phase voltage threshold, executing the step of determining the corresponding principal component scores of feeders in the preset short-time window zero-sequence instantaneous power curve cluster based on the zero-sequence current and the zero-sequence voltage.
